(19) United States
(12) Patent Application Publication
(10) Pub. No.: US 2017/0194947 A1
(43) Pub. Date: Jul. 6, 2017

(54) SIGNAL SELF-CALIBRATION CIRCUITS AND METHODS

(71) Applicant: MediaTek Singapore Pte. Ltd., Singapore (SG)

(72) Inventor: Cwei WEI, Chaohu City (CN)

(21) Appl. No.: 15/395,374

(22) Filed: Dec. 30, 2016

(30) Foreign Application Priority Data
Jan. 5, 2016 (CN) 201610006239.9

(51) Int. Cl. H03K 3/017; H03K 3/0233

(52) U.S. Cl. CPC H03K 3/017; H03K 3/0233

(57) ABSTRACT

A signal self-calibration circuit and a signal self-calibration method are provided. The signal self-calibration circuit includes a comparator, a switcher, and an output-stage circuit. The comparator has a non-inverting input terminal and an inverting input terminal. An input signal and a reference signal are alternately input to the non-inverting input terminal and the inverting input terminal of the comparator. The switcher switches the input signal and the reference signal which are input to the non-inverting input terminal and the inverting input terminal of the comparator when a rising edge occurs at an output signal of the comparator. The output-stage circuit generates a square-wave signal with a duty ratio of 50% according to the output signal of the comparator.

### CROSS REFERENCE TO RELATED APPLICATIONS

This Application claims priority of Chinese Patent Application No. 201610006239.9, filed on Jan. 5, 2016, the entirety of which is incorporated by reference herein.

### BACKGROUND OF THE INVENTION

Field of the Invention

The invention relates to signal processing technique, and particularly, to a signal self-calibration circuit and method.

Description of the Related Art

In the field of signal processing, a shaping process for input signals is a common procedure. One example of this is the Sony, Philips Digital Interface Format (SPDIF) signal. SPDIF is the abbreviation of the digital audio interfaces used by SONY and PHILIPS for audio data transmission. However, SPDIF is applied only for transmission of digital signals. Thus, before an input signal enters SPDIF, the input signal must be processed by shaping or by an analog-to-digital conversion through an SPDIF buffer, so that the input signal when entering the SPDIF is a square wave with an acceptable duty ratio (such as 40%-60%).

In the conventional method, a comparator is usually applied to compare an input signal with a reference signal to obtain a square wave. For a symmetric input signal, the ideal output signal obtained by comparing the input signal with a reference signal is a square wave with a duty ratio of 50%. However, the comparator itself has an offset voltage. Thus, the duty ratio of the digital signal actually output from the comparator is usually lower than 50%.

SPDIF is used to read data “0” and “1” of a digital input signal and sensitive to the duty ratio of the input signal. If the duty ratio of the actual digital input signal is too low, for example lower than an acceptable range, SPDIF cannot easily extract data “0” and “1”, which causes an incorrect determination for the data of the input signal, resulting in the distortion of the obtained signal.

### BRIEF SUMMARY OF THE INVENTION

An exemplary embodiment of a signal self-calibration circuit is provided. The signal self-calibration circuit comprises a comparator, a switcher, and an output-stage circuit. The comparator has a non-inverting input terminal and an inverting input terminal. An input signal and a reference signal are alternately input to the non-inverting input terminal and the inverting input terminal of the comparator. The switcher switches the input signal and the reference signal which are input to the non-inverting input terminal and the inverting input terminal of the comparator when a rising edge occurs at an output signal of the comparator. The output-stage circuit generates a square-wave signal with a duty ratio of 50% according to the output signal of the comparator.

Another exemplary embodiment of a signal self-calibration method is provided. The signal self-calibration method comprises the steps of switching an input signal and a reference signal which are input to a non-inverting input terminal and an inverting input terminal of a comparator respectively when a rising edge occurs at an output signal of the comparator; and generating a square-wave signal with a duty ratio of 50% according to the output signal of the comparator.

With the signal self-calibration circuit and method disclosed in the invention, even though there is a relatively high offset voltage at one input terminal of the comparator, a square-wave signal with duty ratio of 50% can be still generated, so that the tolerance for the voltage offset of the comparator is greatly increased.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic view showing a waveform of an ideal digital signal by using a comparator;

FIG. 2 is a schematic view showing the digital signal V_{d} generated when there is an offset voltage in a reference-signal input terminal of a comparator;

FIG. 3 shows an exemplary embodiment of a signal self-calibration circuit 300;

FIG. 4 is a schematic diagram illustrating switching of input signals of a comparator in the signal self-calibration circuit of FIG. 3;

FIG. 5 is a schematic diagram illustrating change in an output signal of the signal self-calibration circuit of FIG. 3;

FIG. 6 shows an exemplarity embodiment of a switcher 32 in the signal self-calibration circuit of FIG. 3;

FIG. 7 shows an exemplary embodiment of an output-stage circuit 33 in the signal self-calibration circuit of FIG. 3;

FIG. 8 is a schematic view showing change in signals of a first D flip-flop 331 in the signal self-calibration circuit of FIG. 3;

FIG. 9 is a schematic view showing change in signals of the signal self-calibration circuit of FIG. 3;

FIG. 10 shows a flow chart of an exemplary embodiment of a signal self-calibration method; and

FIGS. 11A and 11B show a schematic view showing comparison between two different greatest tolerances for a voltage offset of a comparator.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

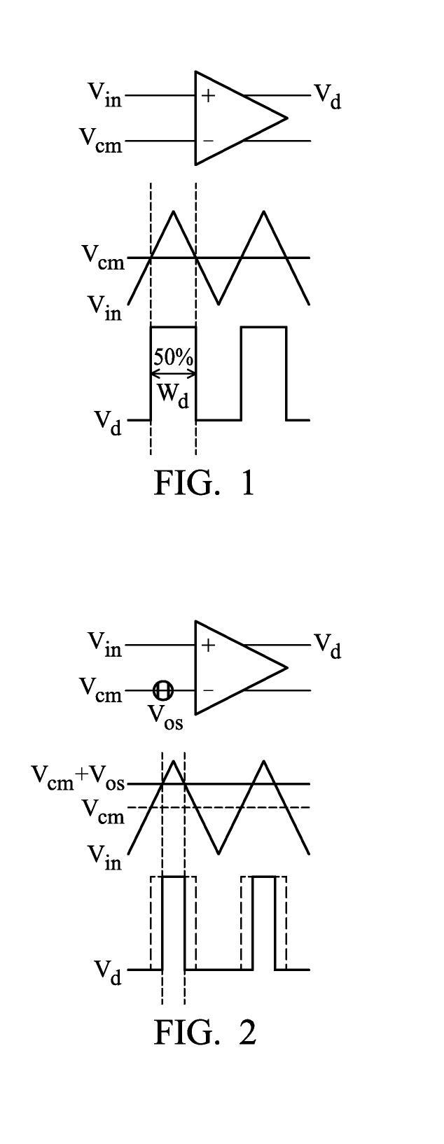

FIG. 1 is a schematic view showing a waveform of an ideal output digital signal by using a comparator. Referring to FIG. 1, the non-inverting input of the comparator receives an input signal Vᵢₙ, the inverting input thereof receives a reference signal V_{cm}, and the output terminal thereof outputs an ideal digital signal V_{d}. In an ideal case, there is no offset voltage in the comparator, and the digital signal V_{d} is an ideal square-wave signal with the duty ratio of 50%. As shown in FIG. 1, the pulse width of the square-wave signal is W_{d}. When the ideal digital signal V_{d} serves as an input signal of an SPDIF audio interface, the ideal digital signal V_{d} can be identified, which prevents occurrence of signal distortion.

However, in practice, there is an offset voltage Vₒₛ in the input terminal of the comparator which receives the reference signal. The variance of the signals in the comparator in an actual case is shown in FIG. 2. FIG. 2 is a schematic view showing the digital signal V_{d} generated when there is an offset voltage in a reference-signal input terminal of a comparator. In the waveform of the digital signal V_{d} of FIG. 2, the solid line represents the digital signal V_{d} generated when there is an offset voltage, while the dotted line represents the digital signal V_{d} generated when there is no offset voltage (that is in an ideal case).

In FIG. 2, the comparator receives an input signal Vᵢₙ and a reference signal V_{cm}. Due to the effect caused by an offset voltage Vₒₛ, the duty ratio of the obtained digital signal V_{d} is less than 50%. For SPDIF, when the duty ratio of the input digital signal V_{d} is less than an acceptable range (for example, the duty ratio is less than 40%), the digital signal V_{d} cannot be identified easily, which causes incorrect identification and signal distortion for the digital signal V_{d}. It should be understood that the input signal Vᵢₙ herein is an example for illustration without limitation for the present invention. Any input signal from which an ideal square-wave signal with a duty ratio of 50% may be derived through a comparator without offset voltage can serve as the input signal Vᵢₙ of the present invention.

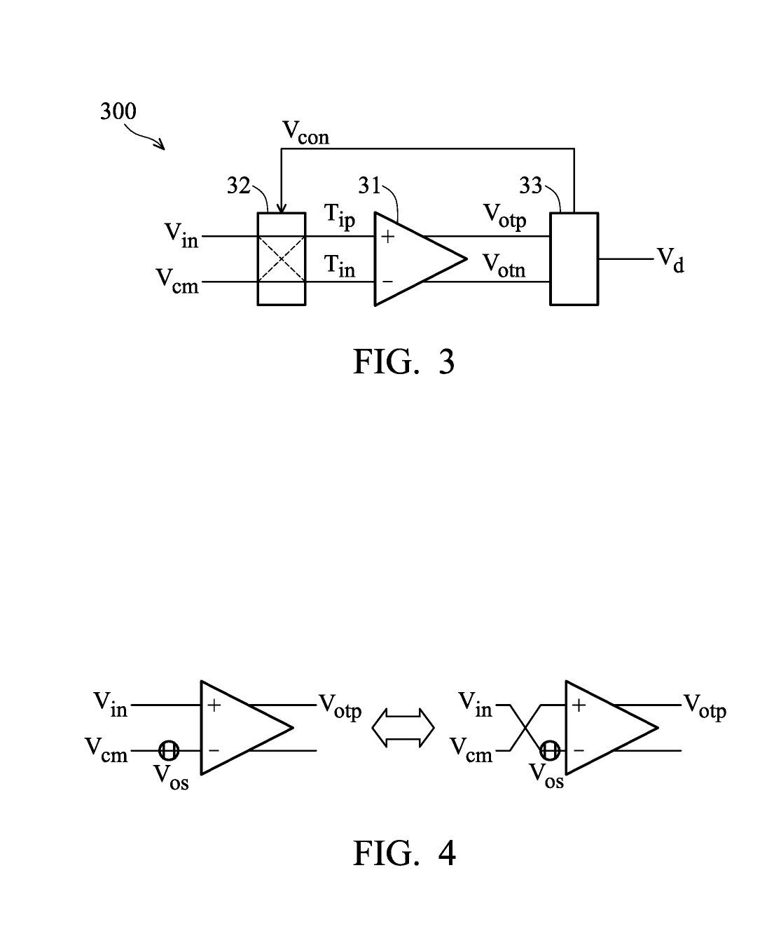

In the embodiment, a digital-signal self-calibration circuit is applied to avoid the effect caused by a comparator with an offset voltage. FIG. 3 shows an exemplary embodiment of a signal self-calibration circuit 300. Referring to FIG. 3, the self-calibration circuit 300 comprises a comparator 31, a switcher 32, and an output-stage circuit 33.

An input signal Vᵢₙ is input to a non-inverting input terminal Tᵢₚ or an inverting input terminal Tᵢₙ of the comparator 31 through the switcher 32, and a reference signal V_{cm} is input to the inverting input terminal Tᵢₙ or the non-inverting input terminal Tᵢₚ of the comparator 31 through the switcher 32. There is an offset voltage Vₒₛ at the inverting input terminal Tᵢₙ of the comparator 31. When the voltage at the non-inverting input terminal Tᵢₚ of the comparator 31 is higher than the voltage at the inverting terminal Tᵢₙ thereof, a voltage (output signal) Vₒₜₚ generated at one output terminal of the comparator 31 is at a high level. On the contrary, the voltage at the non-inverting input terminal Tᵢₚ of the comparator 31 is less than the voltage at the inverting terminal Tᵢₙ thereof, the voltage Vₒₜₚ generated at the output terminal of the comparator 31 is at a low level.

Specifically, when a rising edge occurs at the output signal Vₒₜₚ of the comparator 31, the switcher 32 switches the input signals at the non-inverting input terminal and the inverting input terminal of the comparator 31.

The output-stage circuit 33 is coupled to the comparator 31. The output-stage circuit 33 generates a digital square-wave signal V_{d} with a pulse width T_{d} and a duty ratio of 50%. When a rising edge occurs at the output signal Vₒₜₚ of the comparator 31, the voltage level of the digital square-wave signal V_{d} generated by the output-stage circuit 33 is inverted.

Furthermore, when a rising edge occurs at the output signal Vₒₜₚ of the comparator 31, the output-stage circuit 33 provides a control signal V_{con} which is used to control the switcher 32 to switch the input signal Vᵢₙ and the reference signal V_{cm} of the comparator 31. Specifically, when a rising edge occurs at the output signal Vₒₜₚ of the comparator 31, the output-stage circuit 33 can generate the control signal V_{con} to the switcher 32 for switching the input signal Vᵢₙ and the reference signal V_{cm}.

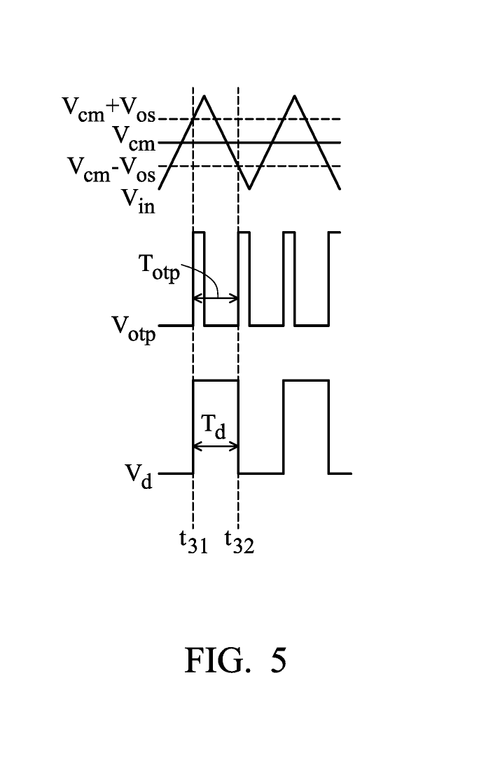

Referring to FIGS. 4 and 5, FIG. 4 is a schematic diagram illustrating the switching of the input signals of the comparator 31 in the signal self-calibration circuit. FIG. 5 is a schematic diagram illustrating the change in the signals of the signal self-calibration circuit.

In the embodiment, firstly, the input signal Vᵢₙ is input to the non-inverting input terminal Tᵢₚ of the comparator 31, and the reference signal V_{cm} is input to the inverting input terminal Tᵢₙ. There is an offset voltage Vₒₛ in the inverting input terminal Tᵢₙ of the comparator 31. In the embodiment, the offset voltage Vₒₛ is a positive offset for the inverting input terminal Tᵢₙ. Thus, the signal at the non-inverting input terminal Tᵢₚ of the comparator 31 is the input signal Vᵢₙ, while the signal at the inverting input terminal Tᵢₙ is V_{cm}+Vₒₛ. The above inference can be also used for the case that the offset voltage Vₒₛ is a negative offset or an offset voltage for the non-inverting input terminal Tᵢₚ.

The process of the change in the signals in the signal self-calibration circuit 300 is described in the following.

At the initial state before the time point t₃₁, Vᵢₙ<V_{cm}+Vₒₛ, that is, the signal Vᵢₙ at the non-inverting input terminal of the comparator 31 is less than V_{cm}+Vₒₛ at the inverting input terminal of the comparator 31. The output signal Vₒₜₚ of the comparator 31 is at a low voltage level, while the output signal Vₒₜₙ thereof is at a high voltage level. The following only discusses the output signal Vₒₜₚ. Since the output signal Vₒₜₙ is inverse to the output signal Vₒₜₚ, the voltage level of the output signal Vₒₜₙ can be inferred based on similar reasons of the output signal Vₒₜₚ.

At the time point t₃₁, Vᵢₙ>V_{cm}+Vₒₛ, and the output signal Vₒₜₚ is switched to the high voltage level from the low voltage level, that is, a rising edge occurs at the output signal Vₒₜₚ of the comparator 31. Then the switcher 32 switches the input signals at the non-inverting input terminal and the inverting input terminal of the comparator 31. The input signal Vᵢₙ is switched to be coupled to the inverting input terminal of the comparator 31, while the reference signal V_{cm} is switched to be coupled to the non-inverting input terminal thereof. At this time, the signal at the non-inverting input terminal of the comparator 31 is V_{cm}, while the signal at the inverting input terminal thereof is Vᵢₙ+Vₒₛ, wherein V_{cm}<Vᵢₙ+Vₒₛ.

After the time point t₃₁, since the signals at the two input terminals of the comparator 31 had been switched and V_{cm}<Vₘ+Vₒₛ (that is, Vᵢₙ>V_{cm}−Vₒₛ), the output signal Vₒₜₚ is switched to the low voltage level from the high voltage level. The output signal Vₒₜₚ remains at the low voltage level until the time point t₃₂.

At the time point t₃₂, Vᵢₙ<V_{cm}−Vₒₛ, that is, the signal V_{cm} at the non-inverting input terminal of the comparator 31 is greater than Vᵢₙ+Vₒₛ at the inverting input terminal thereof. The output signal Vₒₜₚ is switched to the high voltage level from the low voltage level again. At this time, anther rising edge occurs at the output signal Vₒₜₚ of the comparator 31. The switcher 32 switches the input signal input signal Vᵢₙ and the reference signal V_{cm} again, and the above steps are repeated.

By continuously switching the input signals at the non-inverting input terminal and the inverting input terminal of the comparator 31, the input signal Vᵢₙ and the reference signal V_{cm} can be switched to be alternately input to the non-inverting input terminal and the inverting input terminal of the comparator 31. The obtained output signal Vₜₒₚ of the comparator 31 has a plurality of pulses. The time interval Tₒₜₚ between two adjacent rising edges is a base pulse width T_{d}. The base pulse width T_{d} is the pulse width of the ideal square-wave signal which is obtained after the input signal Vᵢₙ is transformed. In other words, the base pulse width T_{d} is equal to a half of the period of the ideal square-wave signal V_{d} which is obtained without offset voltage in the comparator 31. According to the output signal Vₒₜₚ, the output-stage circuit 33 can generate the square-wave signal V_{d} with the pulse width T_{d} and the duty ratio of 50%, as shown in FIG. 5.

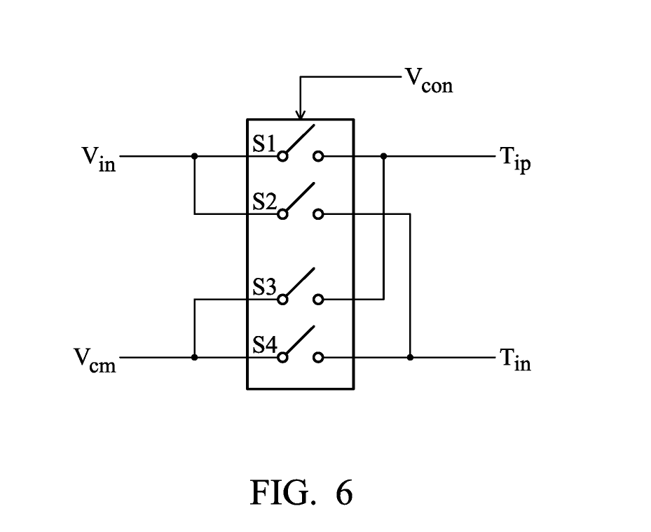

FIG. 6 shows an exemplarity embodiment of the switcher 32 in the self-calibration circuit. The switcher 32 comprises four switching elements S1-S4. The control signal V_{con} controls the switching elements S1-S4 to be turned on or off. As shown in FIG. 6, the input signal Vᵢₙ are coupled to the non-inverting input terminal or the inverting input terminal through the switching element S1 or S2, and the reference signal V_{cm} are coupled to the non-inverting input terminal or the inverting input terminal through the switching element S3 or S4. The switching elements S1 and S4 are turned on or off at the same time, and the switching elements S2 and S3 are turned on or off at the same time. When the switching elements S1 and S4 are turned on and the switching elements S2 and S3 are turned off, the input signal V₁ is input to the non-inverting input terminal Tᵢₚ of the comparator 31, and the reference signal V_{cm} is input to the inverting input terminal Tᵢₙ of the comparator 31. When the switching elements S1 and S4 are turned off and the switching elements S2 and S3 are turned on, the input signal Vᵢₙ is input to the inverting input terminal Tᵢₙ of the comparator 31, and the reference signal V_{cm} is input to the non-inverting input terminal Tᵢₚ of the comparator 31. The switching elements S1-S4 can be implemented by N-type or P-type field effect transistors. For example, the switching elements S1 and S4 are N-type field effect transistors, while the switching elements S2 and S3 are P-type field effect transistors; and vice versa. Please note that FIG. 6 just shows one embodiment of the switcher 32. One skilled in the art can use any circuit or device which is capable of performing the above operation or function to achieve the switcher 32.

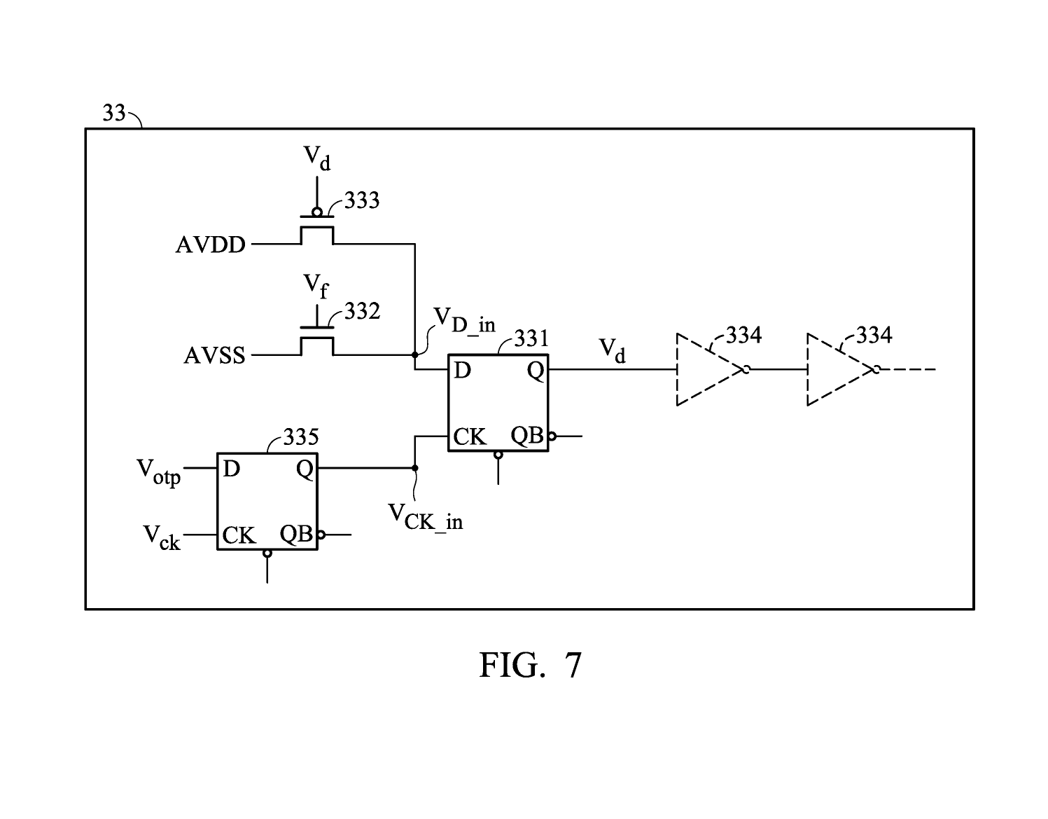

FIG. 7 shows an exemplary embodiment of the output-stage circuit 33 in the self-calibration circuit 300. The output-stage circuit 33 comprises a first D flip-flop 331, switches 332 and 333. For example, the switch 332 can be an N-type or P-type field effect transistor, and the switch 333 can be a P-type or N-type field effect transistor. In the embodiment, for illustration, the switch 332 is an N-type field effect transistor, and the switch 333 is a P-type field effect transistor.

The clock (CK) input terminal of the first D flip-flop 331 is coupled to the output terminal of the comparator 31, that is, the input signal V_{CK}_{_}ᵢₙ at the CK input terminal of the first D flip-flop 331 is the output signal Vₒₜₚ of the comparator 31. The first D flip-flop 331 is triggered by the output signal Vₒₜₚ of the comparator 31 and generates the digital square-wave signal V_{d} at the Q output terminal.

A high supply voltage (such as a high-level voltage) AVDD is coupled to the data (D) input terminal of the first D flip-flop through the switch 333, and a low supply voltage (such as a low-level voltage serving a ground voltage) AVSS is also coupled to the D input terminal of the first D flip-flop 331 through the switch 332. The switches 332 and 333 are both controlled by the output signal V_{d} of the first D flip-flop 331. For the implementation of the field effect transistors, the type of the switch 332 and the type of the switch 333 are complementary to each other. Thus, at the same time, one of the switches 332 and 333 is turned on, and the other is turned off.

For example, when the output signal V_{d} at the Q output terminal of the first D flip-flop 331 is at a high voltage level, the switch 333 shown in FIG. 7 is turned off, and the switch 332 shown in FIG. 7 is turned on. Accordingly, the input signal V_{D}_{_}ᵢₙ at the D input terminal of the first D flip-flop 331 is at the low voltage level of the low supply voltage AVSS. When the output signal V_{d} at the Q output terminal of the first D flip-flop 331 is switched to a low voltage level, the switch 333 shown in FIG. 7 is turned on, and the switch 332 shown in FIG. 7 is turned off. Accordingly, the input signal V_{D}_{_}ᵢₙ at the D input terminal of the first D flip-flop 331 is at the high voltage level of the high supply voltage AVDD.

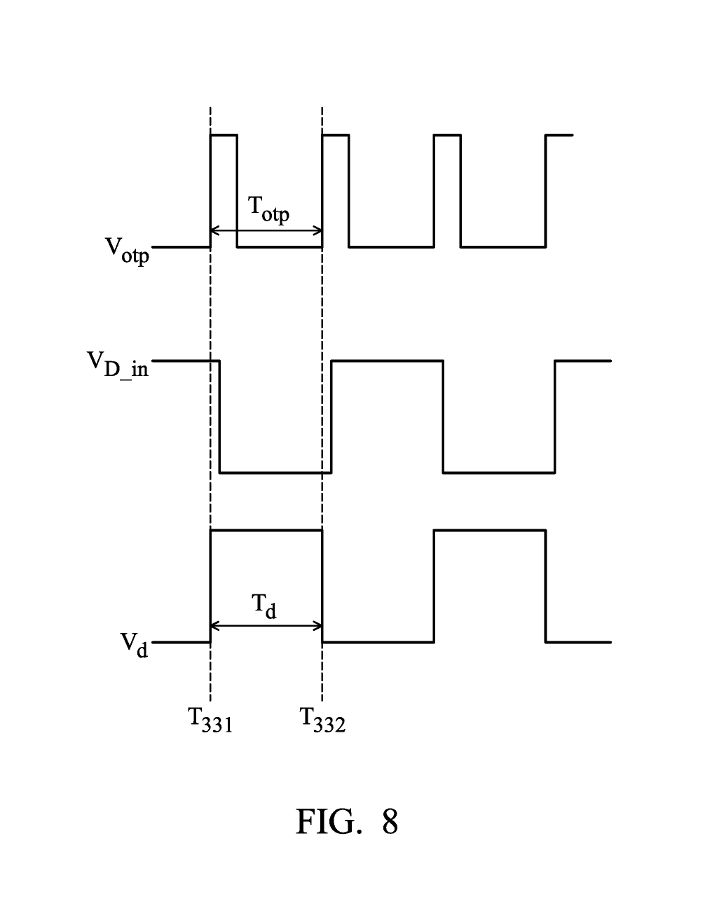

FIG. 8 is a schematic view showing the change in the signals of the first D flip-flop 331 in the self-calibration circuit 300.

The input signal V_{CK}_{_}ᵢₙ at the CK input terminal of the first D flip-flop 331 can be Vₒₜₚ which is the output signal at the output terminal of the comparator 31. The time interval Tₒₜₚ between two adjacent rising edges of the output signal Vₒₜₚ is the base pulse width T_{d}. The input signal at the D input terminal of the first D flip-flop 331 is V_{D}_{_}ᵢₙ. The output signal at the Q output terminal of the first D flip-flop 331 is V_{d}.

Assume that at the initial state (that is, before the time point t₃₃₁), the signal Vₒₜₚ is at a low voltage level, and the signal V_{d} is a low voltage level. Thus, the switch 333 which is implemented by a P-type field effect transistor is turned on, and the signal V_{D}_{_}ᵢₙ at the D input terminal is at a high voltage level.

When a rising edge occurs at the output signal Vₜₒₚ at the time point t₃₃₁, the signal V_{d} is switched to a high voltage level according to the input signal V_{D}_{_}ᵢₙ. The signal V_{d} with the high voltage level then turns on the switch 332 implemented by an N-type field effect transistor and turns off the switch 333 implemented by the P-type field effect transistor. Thus, the signal V_{D}_{_}ᵢₙ at the D input terminal is switched to a low voltage level.

During the period between the time point t₃₃₁ to the time point t₃₃₂, no rising edge occurs at the output signal Vₒₜₚ, and the signal V_{d} remains at the high voltage level.

When another rising edge occurs at the output signal Vₒₜₚ at the time point t₃₃₂, the signal V_{d} is switched to the low voltage level according to the input signal V_{D}_{_}ᵢₙ. Then, the switch 333 implemented by the P-type field effect transistor is turned on, and the signal V_{D}_{_}ᵢₙ at the D input terminal is switched to the high voltage level. The above steps are repeated.

According to FIG. 8, when a rising edge occurs at the output signal Vₒₜₚ of the comparator, the voltage level of the Q output terminal of the first D flip-flop 331 is inverted. That is, whenever a rising edge occurs at the output signal Vₒₜₚ of the comparator, the voltage level of the square-wave signal generated by the output-stage circuit is inverted. Thus, the voltage level of the signal outputted by the output-stage circuit 33 inverts at every rising edge of the output signal Vₒₜₚ of the comparator, thereby generating the digital square-wave signal V_{d} with the duty cycle of 50%.

Moreover, the digital square-wave V_{d} generated by the first D flip-flop 331 can serve as the control signal V_{con} of the switcher 32 shown in FIG. 6 to switch the signals input to the non-inverting input terminal and the inverting input terminal of the comparator 31. When the voltage level of the output signal V_{d} at the Q output terminal of the first D flip-flop 331 changes, the switcher 32 switches the signals input to the non-inverting input terminal and the inverting input terminal of the comparator 31. As described above, the voltage level of the output signal V_{d} of the output-stage circuit 33 changes whenever a rising edge occurs at the output signal Vₒₜₚ of the comparator. Thus, equivalently, when a rising edge occurs at the output signal Vₒₜₚ of the comparator, the switcher 32 switches the signals input to the non-inverting input terminal and the inverting input terminal of the comparator 31.

In other embodiments, the output-stage circuit 33 further comprises a second D flip-flop 335 used to synchronize the signal Vₒₜₚ input to the CK input terminal of the first D flip-flop 331 with the system clock V_{ck}. The D input terminal of the second D flip-flop 335 receives the signal Vₒₜₚ from the comparator 31, the CK input terminal thereof receives the system clock V_{ck} to serve as the trigger clock, and the Q output terminal thereof generates a signal to serve as the input signal V_{CK}_{_}ᵢₙ of the CK input terminal of the first D flip-flop 331.

The signal V_{CK}_{_}ᵢₙ which is the version of the signal Vₒₜₚ synchronized with the system clock is used to trigger the first D flip-flop 331 for achieving clock synchronization in the whole signal self-calibration circuit 300.

In another embodiment, the output-stage circuit 33 may further comprise two inverting buffers 334. The output signal V_{d} at the Q output terminal of the first D flip-flop 331 is input to the two inverting buffers 334 and then the latter buffer 334 outputs a digital square-wave signal with the pulse width T_{d} and the duty ratio of 50%.

The connection related to the non-inverting output terminal of the comparator 31 is described above. For the inverting output terminal of the comparator 31, a similar connection may be arranged.

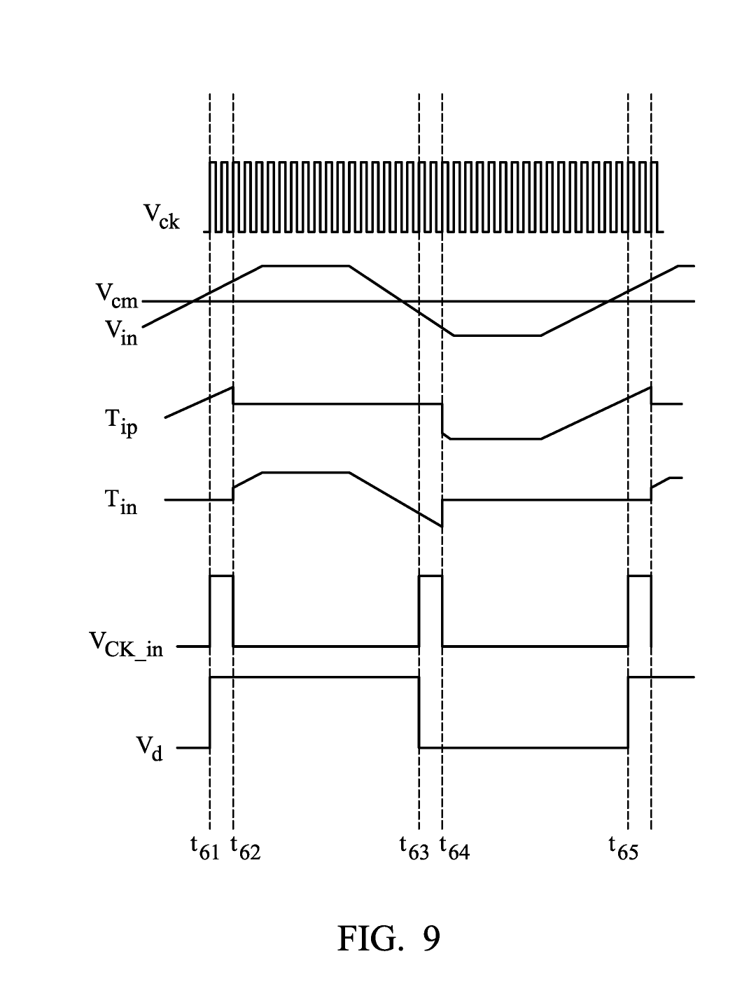

FIG. 9 is a schematic view showing the change in the signals of the self-calibration circuit 300.

The input signal Vᵢₙ and the reference signal V_{cm} are input to the comparator 31 through the switcher 32. Tᵢₚ and Tᵢₙ shown in FIG. 9 represent the signals at the non-inverting input terminal Tᵢₚ and the inverting input terminal Tᵢₙ of the comparator 31 respectively. The output signal Vₒₜₚ of the comparator 31 is clock (system clock V_{ck}) synchronized as the signal V_{CK}_{_}ᵢₙ to serve as the input signal at the CK input terminal of the first D flip-flop 331 in the output-stage circuit 33. The digital square-wave signal V_{d} is the output signal of the self-calibration circuit 300. V_{ck} represents the system clock.

The specific process of the change in the signals is shown in the following:

In the initial state, the non-inverting input terminal of the comparator receives the input signal Vᵢₙ, and the inverting input terminal thereof receives the reference signal V_{cm}. And there is offset Vₒₛ the inverting input terminal of the comparator. At this time, Vᵢₙ<V_{cm}+Vₒₛ.

From the time point t₆₁, Vᵢₙ>V_{cm}+Vₒₛ. The comparator 31 outputs the signal Vₒₜₚ with a high voltage level which becomes the signal V_{CK}_{_}ᵢₙ by being processed with the clock synchronization. That is, a rising edge occurs at the output signal of the comparator 31.

The signal V_{CK}_{_}ᵢₙ serve as the trigger clock of the first D flip-flop 331 in the output-stage circuit 33, so that the voltage level of the digital square-wave signal V_{d} generated by the output-stage circuit 33 is inverted. The digital signal V_{d} serves as the control signal V_{con} of the switcher 32. When the voltage level of the digital signal V_{d} is inverted, the switcher 32 switches the coupling of the input signal Vᵢₙ and the reference signal V_{cm} at the time point t₆₂. As shown in FIG. 9, the input signals at the non-inverting input terminal Tᵢₚ and the inverting input terminal Tᵢₙ change. The signal at the non-inverting input terminal Tᵢₚ is the reference signal V_{cm}, and the signal at the inverting input terminal Tᵢₙis Vᵢₙ+Vₒₛ. Since V_{cm} is less than Vᵢₙ+Vₒₛ, the signal V_{CK}_{_}ᵢₙ is switched to the low voltage level again.

At the time point t₆₃, the signal V_{cm} at the non-inverting input terminal Tᵢₚ is greater than Vᵢₙ+Vₒₛ at the inverting input terminal Tᵢₙ. Thus, the signal V_{CK}_{_}ᵢₙ is switched to the high voltage level from the low voltage level, that is, a rising edge occurs at the signal V_{CK}_{_}ᵢₙ. Since the signal V_{CK}_{_}ᵢₙ serves as the trigger clock of the first D flip-flop 331 in the output-stage circuit, the voltage level of the digital signal V_{d} generated by the output-stage circuit 33 is inverted again. Then, at the time point t₆₄, the switcher 32 switches the coupling of the input signal Vᵢₙ and the reference signal V_{cm}. As shown in FIG. 9, the input signals at the non-inverting input terminal Tᵢₚ and the inverting input terminal Tᵢₙ change. The signal at the non-inverting input terminal Tᵢₚ is the input signal Vᵢₙ, and the signal at the inverting input terminal Tᵢₙ is V_{cm}+Vₒₛ. Since Vᵢₙ is less than V_{cm}+Vₒₛ, the signal V_{CK}_{_}ᵢₙ is switched to the low voltage level again. Through the above operation loop, the input signal Vᵢₙ and the reference signal V_{cm} can be alternately input to the non-inverting input terminal Tᵢₚ and the inverting input terminal Tᵢₙ of the comparator. The related description is omitted.

Through the above process of the change in the signals, the input signal Vᵢₙ is transformed to the digital signal V_{d} by the signal self-calibration circuit 300. The digital signal V_{d} is used as a control signal of a controller which is fed back to control the switcher, thereby switching the signals at the input terminals of the comparator for achieving the signal self-calibration. Finally, a digital square-wave signal V_{d} with the duty ratio of 50% is obtained. For SPDIF, the digital signal can be identified accurately, which prevents occurrence of signal distortion.

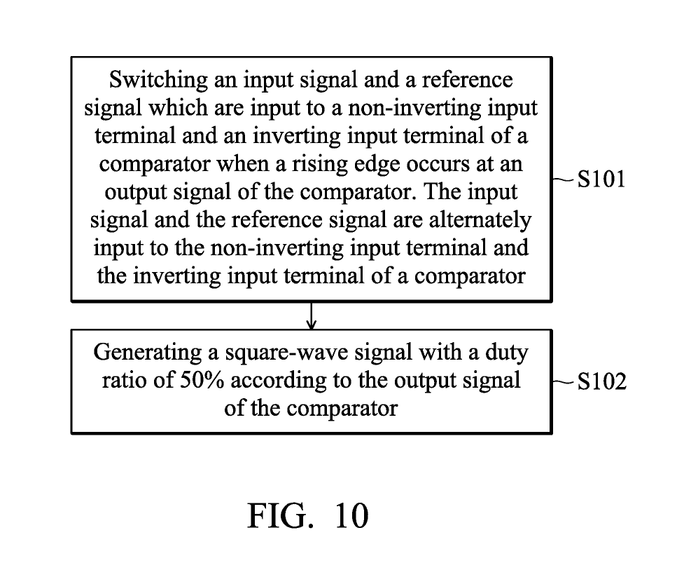

FIG. 10 shows a flow chart of an exemplary embodiment of a signal self-calibration method. The signal self-calibration method is applied to self-calibrate the process of transforming an input signal to a digital signal, thereby preventing the digital signal from distortion. In the embodiment, transformation of an SPDIF digital-audio-interfaces input signal is taken as an example for explaining the embodiment. The signal self-calibration method can be applied for transformation of signals with other types. The embodiment of the signal self-calibration method comprises the following steps of:

S101: switching an input signal and a reference signal input to a non-inverting input terminal and an inverting input terminal of a comparator when a rising edge occurs at an output signal of the comparator, that is, the input signal and the reference signal are alternately input to the non-inverting input terminal and the inverting input terminal of the comparator.

S102: generating a square-wave signal with a duty ratio of 50% according to the output signal of the comparator.

The specific change in the signals can be obtained by referring to FIG. 5 and the description of the outputting process of the signals. The related description is omitted.

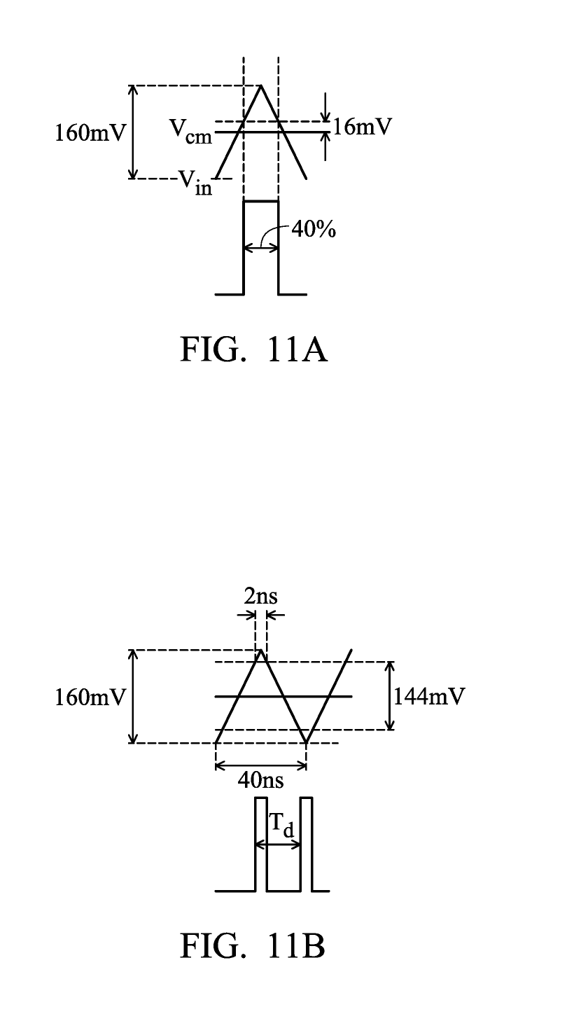

By applying the signal self-calibration circuit and method of the embodiments, the tolerance for the voltage offset of the comparator is greater, which is advantageous to the circuit design. In the following, SPDIF is taken as an example. FIGS. 11A and 11B show a schematic view showing comparison between two different tolerances for a voltage offset of a comparator.

An embodiment will be described by taking an SPDIF input signal whose peak-to-peak value is 160 mV and whose tolerable minimum duty ratio for SPDIF is 40% as an example. As shown in FIG. 11A, the duty ratio of the digital signal V_{d} which can be identified by SPDIF is preferably higher than 40%, and thus the tolerable maximum value of the offset voltage Vₒₛ for the comparator is 16 mV. If the offset voltage Vₒₛ exceeds the largest tolerable value, the duty ratio of the digital signal V_{d} generated by the comparator will be less than 40%, which causes incorrect identification and signal distortion. Note that, 160 mV is just an example for illustration without any limitation for the invention.

By applying the signal self-calibration circuit, as shown in FIG. 11B, the maximum value of the tolerable offset voltage Vₒₛ is 72 mV. For example, in the embodiment, based on the circuit operation process, the narrowest width of the pulse of the output signal Vₒₜₚ of the comparator may be two system clock periods, such as 2 ns. By taking as an example that the half of the clock period of the output signal is 40 ns, the maximum value of the tolerable offset voltage Vₒₛ is 72 mV. Accordingly, through the invention, the tolerance for the offset voltage Vₒₛ of the comparator is greatly increased in the process of obtaining an SPDIF signal.

According to the signal self-calibration circuit and method, when a rising edge occurs at the output signal of the comparator, the signals input to the two input terminals of the comparator are switched, so that the comparator generates a series of pulses and the time interval between any two adjacent pulse is equal to a half of the clock period of the output signal of the signal self-calibration circuit. According to the series of pulses, a digital square-wave signal with the duty ratio of 50% is generated. In this manner, even though there is a relatively high offset voltage at one input terminal of the comparator, a square-wave signal with the duty ratio of 50% can be still generated.

In the embodiments of the signal self-calibration circuit and method, the tolerance for the voltage offset of the comparator is greatly increased. Moreover, the requirement for duty ratio of the digital signal can be achieved by using less power consumption, and the area for the self-calibration can be reduced accordingly.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A signal self-calibration circuit, comprising:
a comparator having a non-inverting input terminal and an inverting input terminal, wherein an input signal and a reference signal are alternately input to the non-inverting input terminal and the inverting input terminal of the comparator;
a switcher, configured for switching the input signal and the reference signal which are input to the non-inverting input terminal and the inverting input terminal of the comparator when a rising edge occurs at an output signal of the comparator; and
an output-stage circuit, configured for generating a square-wave signal with a duty ratio of 50% according to the output signal of the comparator.

2. The signal self-calibration circuit as claimed in claim 1, wherein the output signal of the comparator comprises a series of pulses, and a time interval between any two adjacent pulses of the series of pulses is equal to a half of a period of the square-wave signal.

3. The signal self-calibration circuit as claimed in claim 1, wherein when a rising edge occurs at the output signal of the comparator, the voltage level of the square-wave signal is inverted.

4. The signal self-calibration circuit as claimed in claim 1,
wherein the output-stage circuit comprises a first D flip-flop, a first switch, and a second switch,
wherein a clock input terminal of the first D flip-flop is coupled to an output terminal of the comparator.
wherein a data input terminal of the first D flip-flop is coupled to the first switch and the second switch, and
wherein an output terminal of the first D flip-flop is configured to output the square-wave signal, and the output terminal of the first D flip-flop is coupled to control terminals of the first switch and the second switch to control the first switch and the second switch to be turned on or off.

5. The signal self-calibration circuit as claimed in claim 4, wherein a high supply voltage is coupled to the data input terminal of the first D flip-flop through the first switch, and a low supply voltage is coupled to the data input terminal of the first D flip-flop through the second switch.

6. The signal self-calibration circuit as claimed in claim 5, wherein one of the first switch and the second switch is turned on, while the other one is turned off.

7. The signal self-calibration circuit as claimed in claim 4, wherein the first and second switches are implemented by field effect transistors, and the type of the first switch and the type of the second switch are complementary to each other.

8. The signal self-calibration circuit as claimed in claim 4, wherein the output-stage circuit further comprises two inverters coupled to the output terminal of the first D flip-flop.

9. The signal self-calibration circuit as claimed in claim 1,
wherein the switcher comprises a first switching element, a second switching element, a third switching element, and a fourth switching element,
wherein the input signal is coupled to the non-inverting input terminal through the first switching element and coupled to the inverting input terminal of the comparator through the second switching element, respectively, and
wherein the reference signal is coupled to the non-inverting input terminal through the third switching element and coupled to the inverting input terminal of the comparator through the fourth switching element, respectively.

10. The signal self-calibration circuit as claimed in claim 9, wherein the square-wave signal serves as a control signal of the switcher to control the first switching element, the second switching element, the third switching element, and the fourth switching element to be turned on or off for switching the input signal and the reference signal when a voltage level of the square-wave signal is inverted.

11. The signal self-calibration circuit as claimed in claim 1, wherein the input signal is a Sony, Philips Digital Interface Format (SPDIF) signal.

12. A signal self-calibration method, comprising:
switching an input signal and a reference signal which are input to a non-inverting input terminal and an inverting input terminal of a comparator respectively when a rising edge occurs at an output signal of the comparator; and
generating a square-wave signal with a duty ratio of 50% according to the output signal of the comparator.

13. The signal self-calibration method as claimed in claim 12, wherein a time interval between two adjacent rising edge of the output signal of the comparator is equal to a half of a period of the square-wave signal.

14. The signal self-calibration method as claimed in claim 12, wherein when a rising edge occurs at the output signal of the comparator, a voltage level of the square-wave signal is inverted.

15. The signal self-calibration method as claimed in claim 14, wherein when the voltage level of the square-wave signal is inverted, the input signal and the reference signal are switched.
